(19) United States
(12) Patent Application Publication
(10) Pub. No.: US 2026/0107698 A1
(43) Pub. Date: Apr. 16, 2026

(54) QUANTUM DEVICE, METHOD, AND APPARATUS WITH TUNABLE RESONANT FREQUENCY

(71) Applicant: Samsung Electronics Co., Ltd., Suwon-si (KR)

(72) Inventor: Daeyun KIM, Suwon-si (KR)

(73) Assignee: Samsung Electronics Co., Ltd., Suwon-si (KR)

(21) Appl. No.: 19/079,622

(22) Filed: Mar. 14, 2025

(30) Foreign Application Priority Data
Oct. 15, 2024 (KR) 10-2024-0140551

(51) Int. Cl. H10N 69/00; G06N 10/40; H10N 60/12; H10N 60/80

(52) U.S. Cl. CPC H10N 69/00; G06N 10/40; H10N 60/12; H10N 60/805

(57) ABSTRACT

A quantum device with a tunable resonant frequency including a ferromagnetic link including a ferromagnetic material and a first superconducting layer and a second superconducting layer coupled to each other by the ferromagnetic link, the ferromagnetic link being configured in a magnetization configuration arranged in a first arrangement corresponding to a first resonant frequency of the quantum device or in a second arrangement corresponding to a second resonant frequency of the quantum device.

### CROSS-REFERENCE TO RELATED APPLICATION

This application claims the benefit under 35 USC § 119(a) of Korean Patent Application No. 10-2024-0140551, filed on Oct. 15, 2024, in the Korean Intellectual Property Office, the disclosure of which is incorporated herein in its entirety by reference for all purposes.

### BACKGROUND

### 1. Field

The disclosure relates to a quantum device, method, and apparatus with tunable resonant frequency.

### 2. Description of the Related Art

Since the concept of quantum computers was first introduced in the late 20th century, various studies have been actively conducted to develop quantum computers. Superconducting quantum computers, which utilize the quantum properties of superconductors, are considered the most promising approach among various studies conducted so far.

In superconducting quantum computers, the resonant frequency of quantum devices plays an important role in the performance of superconducting quantum computers, including the accuracy of quantum operations, coupling between quantum devices, and initialization of quantum states. To improve the performance of superconducting quantum computers, there is desire to stably control the resonant frequency of quantum devices.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a quantum device with a tunable resonant frequency including a ferromagnetic link including a ferromagnetic material and a first superconducting layer and a second superconducting layer coupled to each other by the ferromagnetic link, the ferromagnetic link being configured in a magnetization configuration arranged in a first arrangement corresponding to a first resonant frequency of the quantum device or in a second arrangement corresponding to a second resonant frequency of the quantum device.

The magnetization configuration may be configured to generate skyrmions in the first arrangement and to destroy the skyrmions in the second arrangement.

The tunable resonant frequency may be discretely tuned based on an arrangement of the magnetization configuration.

The magnetization configuration may be changed by an applied external signal to be arranged in the first arrangement or the second arrangement.

The tunable resonant frequency of the quantum device may be determined as an arrangement of the magnetization configuration and the magnetization configuration may be changed by an applied external signal.

An application of an external signal may cause a formation of skyrmions to form to implement one of the first resonant frequency and the second resonant frequency.

Each of the first resonant frequency and the second resonant frequency may be reproducible in response to respective external signals being applied to the ferromagnetic link.

The magnetization configuration may be arranged in the first arrangement in response to a first external signal and the magnetization configuration may be changed from the first arrangement to the second arrangement in response to a second external signal.

The quantum device may include a wire arranged adjacent to the ferromagnetic link, processors configured to execute instructions, and a memory storing the instructions, and an execution of the instructions configures the processors to control an electric current flowing through the wire to create external magnetic fields to generate the first external signal and the second external signal, and the first external signal and the second external signal may be selectively applied to the ferromagnetic link by the wire.

An arrangement of the magnetization configuration may be determined based on a direction or a strength of an electric current applied to the ferromagnetic link.

When a first current in a first direction may be applied to the ferromagnetic link, the magnetization configuration is arranged in the first arrangement and when a second current in a second direction opposite to the first direction is applied to the ferromagnetic link, the magnetization configuration may be changed from the first arrangement to the second arrangement.

The quantum device may include a laser configured to apply laser pulses to the ferromagnetic link, processors configured to execute instructions, and a memory storing the instructions, and an execution of the instructions configures the processors to control a strength of a laser pulse of the laser pulses being selectively applied to the ferromagnetic link to change an arrangement of the magnetization configuration.

A time to rearrange the magnetization configuration may be determined based on a duration of the laser pulse applied to the ferromagnetic link.

The quantum device may be a cubit of a quantum circuit.

The quantum device may be a cubit coupler of a quantum circuit.

In a general aspect, here is provided a method of controlling a cubit coupler including coupling cubits by applying a first external signal to the cubit coupler to allow a magnetization configuration of a ferromagnetic link, the ferromagnetic link being configured to couple a first superconducting layer and a second superconducting layer of the cubit coupler, to be arranged in a first arrangement to configure the cubit coupler to have a first resonant frequency and decoupling the cubits by applying a second external signal to the cubit coupler to allow the magnetization configuration of the ferromagnetic link to be arranged in a second arrangement to configure the cubit coupler to have a second resonant frequency.

The magnetization configuration may be configured to generate skyrmions in the first arrangement and to destroy the skyrmions in the second arrangement.

The coupling of the cubits may include applying the first external signal to align the magnetization configuration to be arranged in the first arrangement and removing the first external signal to allow a resonant frequency of the cubit coupler to be maintained as the first resonant frequency.

The decoupling of the cubits may include applying the second external signal to align the magnetization configuration to be arranged in the second arrangement and removing the second external signal to allow a resonant frequency of the cubit coupler to be maintained as the second resonant frequency.

The method may include applying the first external signal and the second external signal to the ferromagnetic link, the first external signal and the second external signal being one of a first external magnetic field and a second external magnetic field, the first external magnetic field and the second external magnetic field having different strengths or directions, a first electric current and a second electric current, the first electric current and the second electric current having different directions or strengths, and a first laser pulse and a second laser pulse, the first laser pulse and the second laser pulse having different strengths.

### BRIEF DESCRIPTION OF THE DRAWINGS

FIG. 1 illustrates an example quantum device according to one or more embodiments.

FIG. 2 illustrates an example magnetization control region of a ferromagnetic link according one or more embodiments.

FIGS. 3A and 3B illustrate example magnetization configurations according one or more embodiments.

FIGS. 4A and 4B illustrate example methods of a quantum device with a tunable resonant frequency according one or more embodiments.

FIGS. 5A to 5D illustrate example quantum devices with tunable resonant frequencies according one or more embodiments.

FIG. 6 illustrates an example method of a quantum device with tunable resonant frequency according one or more embodiments.

FIG. 7 illustrates an example method of operating a cubit coupler according to one or more embodiments.

FIG. 8 illustrates an example electronic device with a superconducting quantum circuit system according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

The use of the term “may” herein with respect to an example or embodiment, e.g., as to what an example or embodiment may include or implement, means that at least one example or embodiment exists where such a feature is included or implemented, while all examples are not limited thereto.

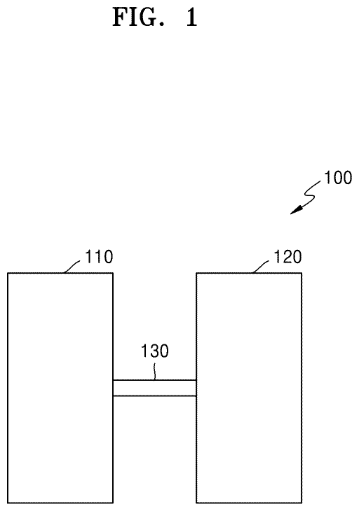

FIG. 1 illustrates an example quantum device according to one or more embodiments. Referring to FIG. 1, in a non-limiting example, a quantum device 100 may include a first superconducting layer 110, a second superconducting layer 120, and a ferromagnetic link 130. However, FIG. 1 only shows components of the quantum device 100 as an example, and the quantum device 100 may include other, additional components.

In an example, the quantum device 100 may be a device included in a quantum circuit of a quantum computer. The quantum device 100 may be a device with quantum properties of superposition. For example, the quantum device 100 may be a cubit. The quantum device 100 may be a device for controlling coupling strength between cubits for quantum computation and the like. For example, the quantum device 100 may be a cubit coupler.

The quantum device 100 may be a device for a superconducting quantum circuit. The quantum device 100 may include a Josephson junction, and in a state of superconductivity, may have quantized energy levels based on the Josephson junction and the oscillations of capacitors.

The first superconducting layer 110 and the second superconducting layer 120 may each include a superconducting material. The first superconducting layer 110 and the second superconducting layer 120 may include the same superconducting material or different superconducting materials. The superconducting material may include one or more of aluminum (Al), niobium (Nb), indium (In), alpha-tantalum (α-Ta), titanium (Ti), lead (Pb), vanadium (V), or a compounds thereof (e.g., NbN, NbTiN, TiN, or VN), but the examples are not limited thereto.

The first superconducting layer 110 and the second superconducting layer 120 may be coupled to each other by the ferromagnetic link 130. The first superconducting layer 110, the second superconducting layer 120, and the ferromagnetic link 130 may form the Josephson junction. The ferromagnetic link 130 may correspond to a weak link of Josephson junction.

The ferromagnetic link 130 may include a ferromagnetic material. The ferromagnetic material may be cobalt (Co), CoFeB, cobalt-nickel (Co—Ni), or cobalt platinum (Co—Pt), but the examples are not limited thereto.

The ferromagnetic link 130 may have a layer structure of a heavy metal layer, a ferromagnetic layer, and an insulating layer. The heavy metal layer may include heavy metal, such as platinum (Pt), tantalum (Ta), or tungsten (W), but the examples are not limited thereto. The ferromagnetic layer may include a ferromagnetic material. The insulating layer may include an insulating material, such as magnesium oxide (MgO), aluminum oxide (AlOx), or tantalum oxide (TaOx), but the examples are not limited thereto. For example, the ferromagnetic link 130 may include at least one of Pt/Co/MgO, Pt/Co/AlOx, Pt/CoFeB/MgO, Pt/(Co—Ni), or Pt/(Co—Pt), but the examples are not limited thereto.

In an example, the quantum device 100 may have a tunable resonant frequency based on the arrangement of a magnetization configuration of the ferromagnetic link 130. The ferromagnetic link 130 may include a magnetization configuration having an arrangement corresponding to a specific resonant frequency to reproduce a specific resonant frequency. This will be described in greater detail below with reference to the accompanying drawings.

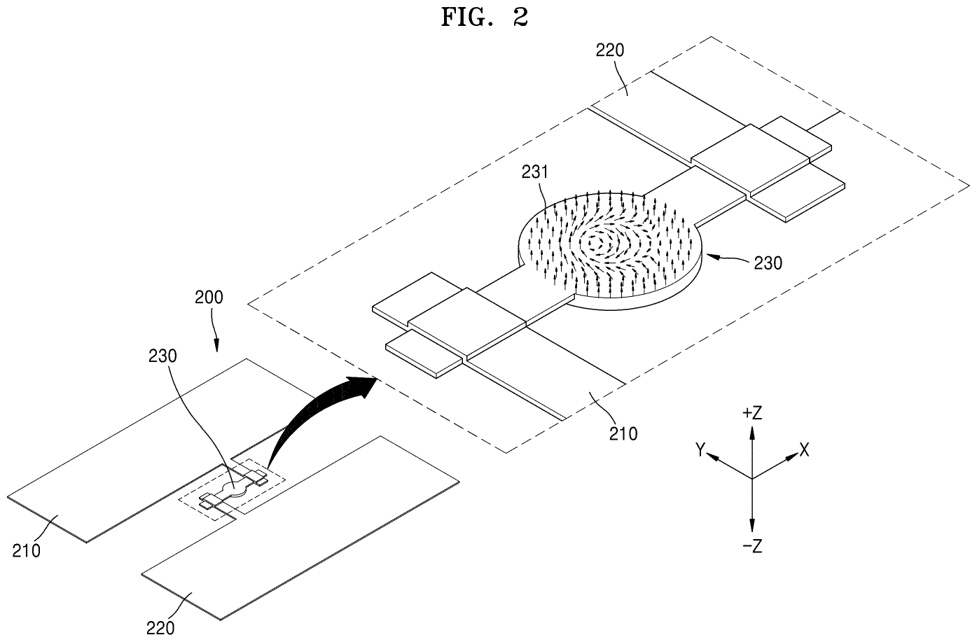

FIG. 2 illustrates an example magnetization control region of a ferromagnetic link according one or more embodiments. Referring to FIG. 2, in a non-limiting example, a magnetization control region 231 of the ferromagnetic link 230 is illustrated. A quantum device 200 may include a first superconducting layer 210, a second superconducting layer 220, and a ferromagnetic link 230. The ferromagnetic link 230 being illustrated is in an enlarged view.

Ferromagnets have magnetic anisotropy, that is, the magnetization (or spin) thereof is aligned in a specific direction. For example, when a ferromagnet exhibits perpendicular magnetic anisotropy, the magnetization of the ferromagnet may be aligned in a vertical direction (e.g., +z and −z axis direction). Alternatively, when a ferromagnet exhibits in-plane magnetic anisotropy, the magnetization of ferromagnet may be aligned in a horizontal direction (e.g., x-y plane direction).

The ferromagnetic link 230 may exhibit perpendicular magnetic anisotropy or in-plane magnetic anisotropy depending on the properties thereof. A magnetization control region 231 of the ferromagnetic link 230 exhibiting perpendicular magnetic anisotropy is described in greater below.

The ferromagnetic link 230 may include the magnetization control region 231. In an example, the magnetization control region 231 may refer to a region where a magnetization configuration may be changed by an external signal, and in this state, the magnetization configuration may mean an arrangement state of magnetization. For example, the distribution or direction of magnetization of the magnetization control region 231 may be changed by an external magnetic field.

In an example, the magnetization control region 231 may have a magnetization configuration that is uniformly distributed in the same direction. In other words, all magnetizations in the magnetization control region 231 may be arranged to face one direction (e.g., a +z axis direction or a −z axis direction). However, but the examples are not limited thereto. In another example, the magnetization control region 231 may have a magnetization configuration that is unevenly distributed in different directions. For example, some magnetizations in the magnetization control region 231 may be arranged to face in one direction (e.g., the +z axis direction), and the other magnetizations may be arranged to face in a direction (e.g., −z axis direction) opposite to the one direction.

At least one area of the ferromagnetic link 230 may be the magnetization control region 231. For example, the magnetization control region 231 may be an area separated from the first superconducting layer 210 and the second superconducting layer 220. The shape of the magnetization control region 231 may be determined based on the properties of the ferromagnetic link 230. Although an example in which the shape of the magnetization control region 231 is a disc shape is illustrated in the drawing, the examples are not limited thereto. For example, the shape of the magnetization control region 231 may be a rod shape.

Conditions for changing the magnetization configuration may be determined based on the properties of the ferromagnetic link 230. For example, the magnetization configuration may be changed only when an external magnetic field that is greater than a critical value is applied, depending on the properties of the ferromagnetic link 230. As the ferromagnet may maintain the magnetization direction even in a state having no external magnetic field, the magnetization configuration may be maintained without change even after the external magnetic field is removed.

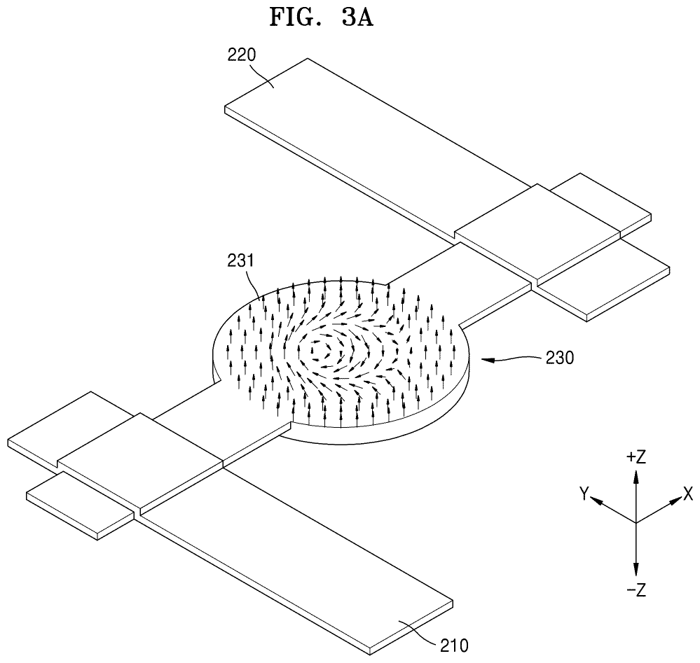

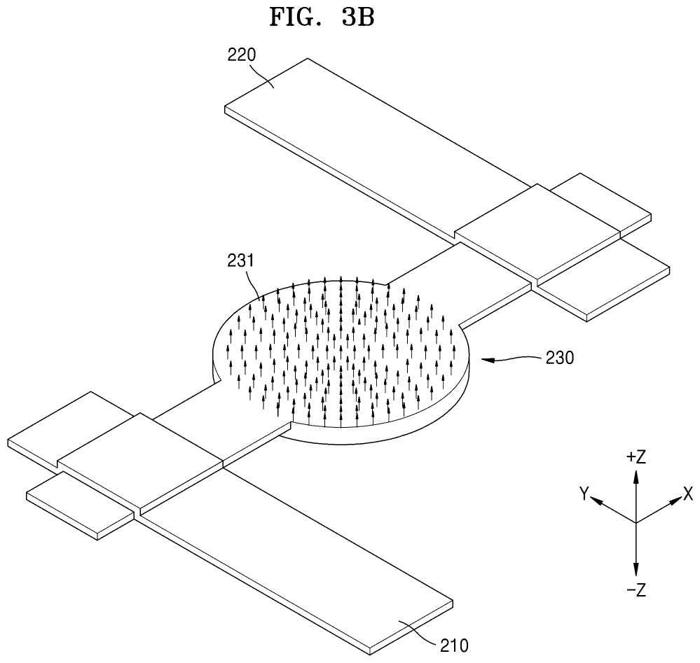

FIGS. 3A and 3B illustrate example magnetization configurations according one or more embodiments. Referring to FIG. 3A, in a non-limiting example, a magnetization configuration in which magnetization in the magnetization control region 231 is arranged in a first arrangement is illustrated. Referring to FIG. 3B, in a non-limiting example, a magnetization configuration in which magnetization in the magnetization control region 231 is arranged in a second arrangement is illustrated.

The first arrangement may be a spin arrangement of a ferromagnet with magnetic skyrmions, and the second arrangement may be a spin arrangement of a ferromagnet without magnetic skyrmions. For example, the first arrangement may refer to a spin arrangement of magnetic skyrmions, and the second arrangement may refer to a parallel spin arrangement.

Referring to FIG. 3A, in the magnetization configuration arranged in the first arrangement, skyrmions may be generated. In an example, skyrmions may mean magnetic skyrmions in which magnetizations are arranged in a vortex shape. The skyrmions may be a magnetization configuration of a nanometer size formed in a vortex shape. The skyrmions may be a magnetization configuration in which the direction of magnetization is gradually changed from the center to an edge of the magnetization control region 231.

For example, at the center of skyrmions, a center magnetization may be arranged to face one direction (e.g., the −z axis direction), at the edge of skyrmions, an edge magnetization may be arranged to face a direction (e.g., the +z axis direction) opposite to the one direction, and in an area from the center to the edge of skyrmions, a central magnetization may be arranged such that the direction of magnetization is gradually changed while spirally rotating.

In an example, the skyrmions may be generated when a first external signal is applied to the ferromagnetic link 230. The first external signal may mean a physical or electrical signal by which a minimum energy needed to generate skyrmions is provided to the ferromagnetic link 230. For example, the first external signal may be an external magnetic field applied to the ferromagnetic link 230.

The skyrmions may be topologically stable. In other words, even when physical impacts are applied to the skyrmions or the applied electrical signal changes, the skyrmions may not be changed or destroyed due to the properties of the ferromagnetic link 230. In this state, the external signal needed to destroy skyrmions may be determined based on the properties of the ferromagnetic link 230.

The skyrmions may be destroyed when a second external signal is applied to the ferromagnetic link 230. In an example, the second external signal may mean a physical or electrical signal by which minimum energy needed to destroy skyrmions is provided to the ferromagnetic link 230.

The first external signal and the second external signal may be physical or electrical signals of the same type. For example, the first external signal and the second external signal may be magnetic fields having different strengths or directions, as external magnetic fields applied to the ferromagnetic link 230. However, the examples are not limited thereto. For example, the first external signal and the second external signal may be physical or electrical signals of different types.

Only when an amount of energy greater than the minimum energy needed to generate skyrmions is applied to the ferromagnetic link 230 may skyrmions be generated in the magnetization control region 231. Furthermore, as the skyrmions have topological stability, unless an amount of energy greater than the minimum energy is applied to the ferromagnetic link 230, the generated skyrmions may not be destroyed. In other words, an application of an amount of energy over a preset critical value is needed to generate or destroy skyrmions, and therefore the magnetization configuration arranged in the first arrangement or the second arrangement may be resistant against external noise.

Referring to FIG. 3B, no skyrmion may be formed in the magnetization configuration arranged in the second arrangement. In the magnetization configuration of FIG. 3B, all magnetizations in the magnetization control region 231 are arranged to face the same direction (e.g., the +z axis direction), and thus skyrmion may not be generated or generated skyrmions may be destroyed.

The maximum current, that is, a critical current, of the ferromagnetic link 230 may vary depending on the magnetization configuration of the magnetization control region 231. For example, the critical current of the ferromagnetic link 230 when the magnetization control region 231 has a magnetization configuration of the first arrangement may be different from the critical current of the ferromagnetic link 230 when and the magnetization control region 231 has magnetization configuration of the second arrangement.

The resonant frequency of a quantum device (e.g., the quantum devices 100 and 200 of FIGS. 1 and 2) may be determined based on the critical current of the ferromagnetic link 230. As the critical current of the ferromagnetic link 230 may vary depending on the magnetization configuration of the magnetization control region 231, the resonant frequency of a quantum device may be determined based on the magnetization configuration of the magnetization control region 231.

For example, the resonant frequency of a quantum device when the magnetization configuration of the magnetization control region 231 is in the first arrangement may be determined as a first resonant frequency, and the resonant frequency of a quantum device when the magnetization configuration of the magnetization control region 231 is in the second arrangement may be determined as a second resonant frequency. The first resonant frequency and the second resonant frequency may be different from each other.

When the magnetization configuration of the magnetization control region 231 is changed from the first arrangement to the second arrangement, the resonant frequency of a quantum device may be changed from the first resonant frequency to the second resonant frequency. On the other hand, when the magnetization configuration of the magnetization control region 231 is changed from the second arrangement to the first arrangement, the resonant frequency of a quantum device may be changed from the second resonant frequency to the first resonant frequency.

By controlling the magnetization configuration of the magnetization control region 231 to be arranged in the first arrangement or the second arrangement, the resonant frequency of a quantum device may be tuned to the first resonant frequency or the second resonant frequency. In other words, by controlling the generation or destruction of skyrmions in the magnetization control region 231, the resonant frequency of a quantum device may be discretely tuned, and as the arrangement of the magnetization configuration of the magnetization control region 231 is robust to noise, the control of the resonant frequency of a quantum device may be also robust to noise.

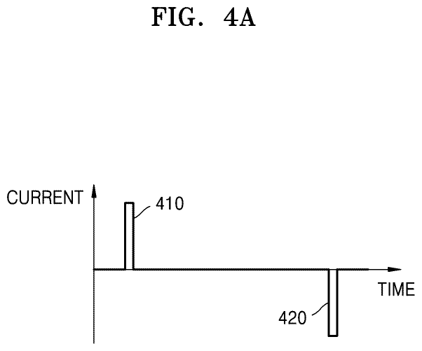

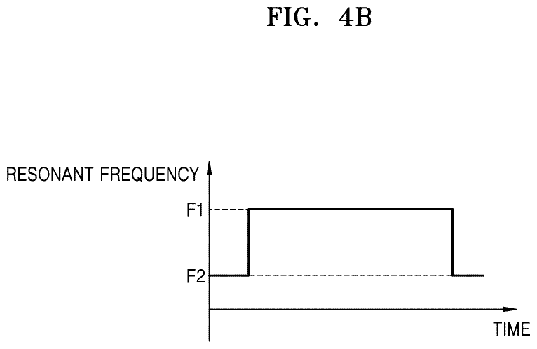

FIGS. 4A and 4B illustrate example methods of a quantum device with a tunable resonant frequency according one or more embodiments. Referring to FIGS. 4A and 4B, in non-limiting examples, when a first current pulse 410 is applied to a ferromagnetic link (e.g., the ferromagnetic link 230 of FIGS. 3A and 3B), a quantum device (e.g., quantum device 200 of FIGS. 3A and 3b) may have a first resonant frequency F1, and when a second current pulse 420 is applied to the ferromagnetic link, the quantum device may have a second resonant frequency F2.

Referring to FIG. 4A, in an example, the quantum device, when an external magnetic field by the first current pulse 410 is applied to the ferromagnetic link, may have the first resonant frequency F1, and when an external magnetic field by the second current pulse 420 is applied to the ferromagnetic link, the quantum device may have the second resonant frequency F2.

For example, the first external magnetic field applied by the first current pulse 410 may be a first external signal. The magnetization configuration of a magnetization control region (e.g., the magnetization control region 231 of FIGS. 3A and 3B) may be arranged in the first arrangement in response to the first current pulse 410. As a result, skyrmions may be generated in the magnetization control region, and the quantum device may have the first resonant frequency F1. As the skyrmions are topologically stable, even when the first current pulse 410 is removed, the resonant frequency of the quantum device may be maintained as the first resonant frequency F1.

The second external magnetic field applied by the second current pulse 420 may be a second external signal. An external magnetic field having the same magnitude as and a different direction from the first current pulse 410 may be applied to the ferromagnetic link by the second current pulse 420, and as a result, the magnetization configuration of the magnetization control region may be changed to the second arrangement so that the skyrmions may be destroyed. In a state in which the skyrmions are destroyed, the quantum device may have the second resonant frequency F2, and unless a separate external signal exists, the resonant frequency of the quantum device may be maintained as the second resonant frequency F2.

In other words, the skyrmions in the magnetization control region may be generated or destroyed by the external magnetic fields applied at different times, and thus, in response to each external magnetic field, the resonant frequency of the quantum device may be discretely tuned.

Furthermore, as the magnitudes and the directions of the first current pulse 410 and the second current pulse 420 are determined based on the properties of the ferromagnetic link, when the first current pulse 410 and the second current pulse 420 with fixed magnitudes and directions are repeatedly applied to the ferromagnetic link, the generation or destruction of skyrmions may be repeatedly reproduced, and as a result, the resonant frequency of the quantum device may also be repeatedly reproduced as the first resonant frequency or the second resonant frequency.

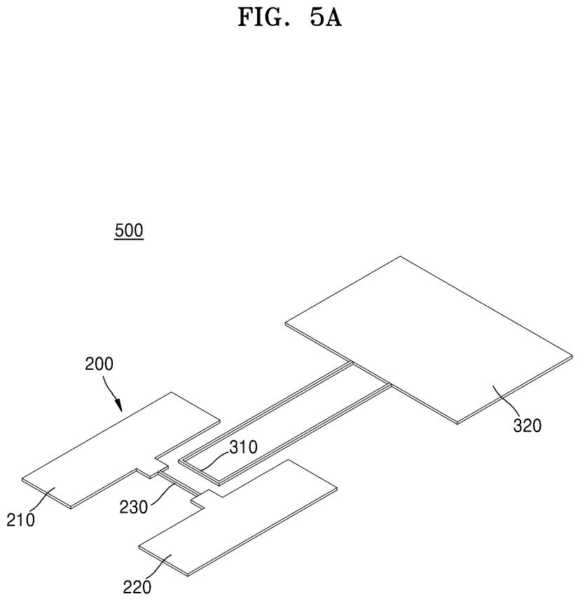

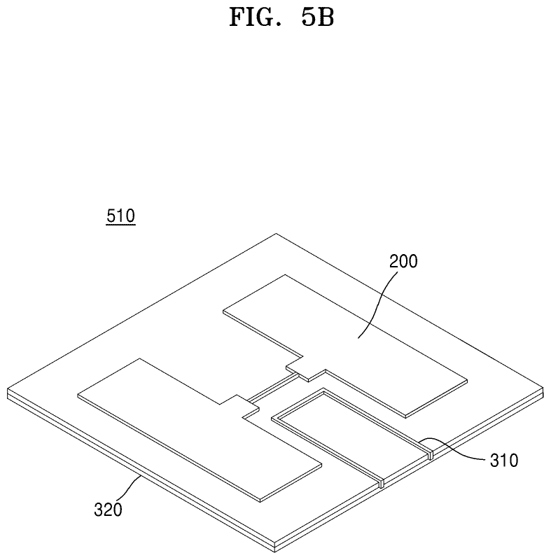

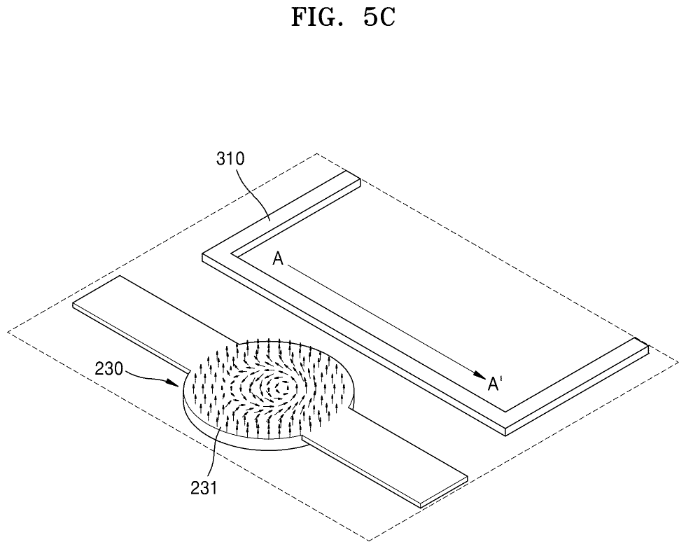

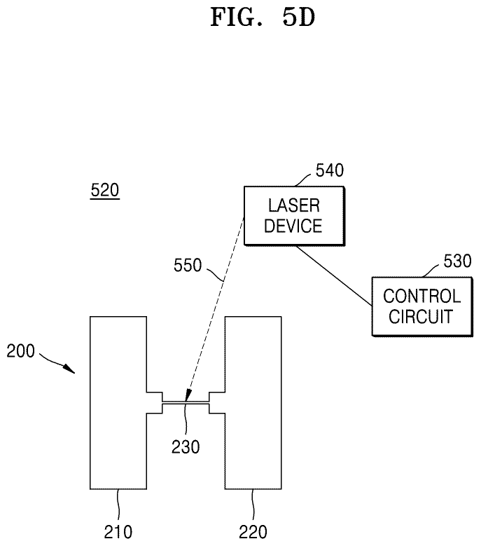

In the following description, a method of changing the magnetization configuration of the magnetization control region to the first arrangement or the second arrangement by using the first current pulse 410 and the second current pulse 420 is described in greater detail below with reference to FIGS. 5A to 5C.

FIGS. 5A to 5D illustrate example quantum devices with tunable resonant frequencies according one or more embodiments. Referring to FIG. 5A, in a non-limiting example, a quantum circuit 500 may include the quantum device 200, an electric wire 310, and a control circuit 320, and the quantum device 200 may include the first superconducting layer 210, the second superconducting layer 220, and the ferromagnetic link 230. The ferromagnetic link 230 may include a magnetization control region (e.g., the magnetization control region 231 of FIGS. 3A and 3B).

Referring to FIGS. 5A and 5B, in a non-limiting example, the first superconducting layer 210, the second superconducting layer 220, and the ferromagnetic link 230 are arranged on a substrate in a planar fashion, but may be arranged in a layer structure. However, examples of the arrangement of the first superconducting layer 210, the second superconducting layer 220, and the ferromagnetic link 230 are not limited thereto.

The quantum device 200, the electric wire 310, and the control circuit 320 may be arranged on the same plane, as illustrated in FIG. 5A, or arranged in layer structure as illustrated for quantum circuit 510 as illustrated in FIG. 5B. The arrangement of the quantum device 200, the electric wire 310, and the control circuit 320 is not limited thereto.

The electric wire 310 may be arranged along the ferromagnetic link 230 between the first superconducting layer 210 and the second superconducting layer 220. The electric wire 310 may be spaced apart from the first superconducting layer 210, the second superconducting layer 220, and the ferromagnetic link 230. In an example, the electric wire 310 may be arranged adjacent to the ferromagnetic link 230.

In an example, the control circuit 320 may control a current flowing in the electric wire 310. When a current flowing through the electric wire 310, an external magnetic field may be generated. Referring to FIG. 5C, in a non-limiting example, a current (e.g., the first current pulse 410 of FIGS. 4A and 4B) may be applied to the electric wire 310 in a direction A-A′. Accordingly, when a first external signal (e.g., an external magnetic field by the first current pulse 410 of FIGS. 4A and 4B) is applied to the ferromagnetic link 230, the magnetization configuration of the magnetization control region 231 is arranged in the first arrangement so that skyrmions may be generated. Due to the topological stability of skyrmions, even when the current flows no longer in the electric wire 310 so that the external magnetic field is removed, the magnetization configuration of the magnetization control region 231 may be maintained in the first arrangement.

Then, a current (e.g., the second current pulse 420 of FIGS. 4A and 4B) may be applied to the electric wire 310 in a direction A′-A. Accordingly, when a second external signal (e.g., an external magnetic field by the second current pulse 420 of FIGS. 4A and 4B) is applied to the ferromagnetic link 230, the magnetization configuration of the magnetization control region 231 may be changed from the first arrangement to the second arrangement so that the skyrmions may be destroyed. Even when the current flows no longer in the electric wire 310 so that the external magnetic field is removed, the magnetization configuration of the magnetization control region 231 may be maintained in the second arrangement.

As the resonant frequency of a quantum device is determined based on the magnetization configuration of the magnetization control region 231, and the magnetization configuration of the magnetization control region 231 remains unchanged unless a current flows in the electric wire 310, a continuous application of current may not be necessary to maintain the magnetization configuration of the magnetization control region 231.

Although a case in which the ferromagnetic link 230 exhibits perpendicular magnetic anisotropy is described above with reference to FIGS. 5A to 5C, when the ferromagnetic link 230 exhibits in-plane magnetic anisotropy, the magnetization configuration of the magnetization control region 231 may be changed by changing the location of the electric wire 310.

Furthermore, although a method of applying an external magnetic field to the ferromagnetic link 230 through a current flowing in the electric wire 310 is described above with reference to FIGS. 5A to 5C, the external magnetic field may be applied by an external ferromagnet, instead of the electric wire 310.

Referring to FIG. 5D, in a non-limiting example, a quantum circuit 520 may include a control circuit 530 and laser device 540. In quantum circuit 520, the first superconducting layer 210, the second superconducting layer 220, and the ferromagnetic link 230 may be provided within lasing range of the laser device 540 so that the laser device 540 may apply a laser pulse 550 to the ferromagnetic link 230.

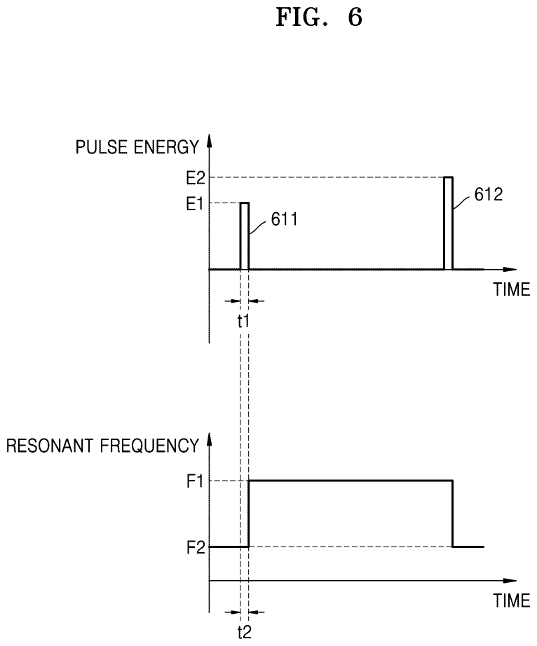

In an example, the control circuit 530 may control the laser device 540 to apply laser pulses 550 to the ferromagnetic link 230. As discussed in greater detail below with respect to FIG. 6, the laser device 540 may be used to control the quantum device 520 to have a tunable resonant frequency.

FIG. 6 illustrates an example method of a quantum device with tunable resonant frequency according one or more embodiments. Referring to FIG. 6, in a non-limiting example, a graph showing an operation method of a quantum device (e.g., quantum device 530) with a tunable resonant frequency is illustrated. In an example, when a first laser pulse 611 is applied to a ferromagnetic link (e.g., the ferromagnetic link 230), the quantum device may have the first resonant frequency F1, and when a second laser pulse 612 is applied to the ferromagnetic link, the quantum device may have the second resonant frequency F2. In an example, the laser pulse may be provided by a laser device (e.g., laser device 530 of FIG. 5) and the laser device may be controlled by a control circuit (e.g., the control circuit 530 and/or electronic device 800).

In an example, when the first laser pulse 611 is applied to the ferromagnetic link, the quantum device may have the first resonant frequency F1, and when the second laser pulse 612 is applied to the ferromagnetic link, the quantum device may have the second resonant frequency F2.

For example, the first laser pulse 611 may be a first external signal. The magnetization configuration of a magnetization control region (e.g., the magnetization control region 231) may be arranged in the first arrangement in response to the first laser pulse 611. As a result, skyrmions may be generated in the magnetization control region, and the quantum device may have the first resonant frequency F1. As the skyrmions are topologically stable, even when the first laser pulse 611 is removed, the resonant frequency of the quantum device may be maintained as the first resonant frequency F1.

In an example, the second laser pulse 612 may be a second external signal. The second laser pulse 612 may be a laser pulse that is stronger than the first laser pulse 611. As the second laser pulse 612 is applied to the ferromagnetic link, the magnetization configuration of the magnetization control region may be changed to the second arrangement, and as a result, the skyrmions may be destroyed. In a state in which the skyrmions are destroyed, the quantum device may have the second resonant frequency F2, and unless a separate external signal exists, the resonant frequency of the quantum device may be maintained as the second resonant frequency F2.

In other words, the skyrmions in the magnetization control region may be generated or destroyed by the first laser pulse 611 and the second laser pulse 612 applied at different times, and thus, in response to each laser pulse, the resonant frequency of the quantum device may be discretely tuned.

Furthermore, the strength of the first laser pulse 611 and the second laser pulse 612 are determined based on the properties of the ferromagnetic link, and as the first laser pulse 611 and the second laser pulse 612 (i.e., energies E1 and E2 of FIG. 6), the pulses having a fixed strength and duration, which are repeatedly applied to the ferromagnetic link, the resulting generation or destruction of skyrmions may be repeatedly reproduced. As a result, the resonant frequency of the quantum device 200 may also be repeatedly reproduced as the first resonant frequency or the second resonant frequency from the respective applications of the first laser pulse 611 and the second laser pulse 612.

In an example, in a method of operating a quantum device (e.g., quantum device 200), by controlling a duration t1 for applying the first laser pulse 611 or the second laser pulse 612 to a ferromagnetic link (e.g., the ferromagnetic link 230), a duration t2 to change the resonant frequency of the quantum device to the first resonant frequency F1 or the second resonant frequency F2 may be controlled.

The duration t2 for generating or destroying skyrmions in a magnetization control region (e.g., the magnetization control region 231) may be determined based on the duration t1 of a laser pulse applied to the ferromagnetic link. As the duration t1 of an applied laser pulse increases, energy may be transmitted more slowly to the ferromagnetic link, and thus, the generation or destruction of skyrmions may be performed more slowly. Reversely, as the duration t1 of an applied laser pulse decreases, energy may be transmitted faster to the ferromagnetic link, the generation or destruction of skyrmions may be performed faster.

In other words, the duration t2 to rearrange the magnetization configuration of the magnetization control region may be determined based on the duration t1 of an applied laser pulse. In an example, in a method of operating a quantum device (e.g., the quantum device 200), the duration t2 to rearrange the magnetization configuration of a magnetization control region (e.g., the magnetization control region 231) may be controlled by adjusting the duration t1 of the laser pulse applied to the ferromagnetic link, and thus, the duration t2 to change the resonant frequency of the quantum device may also be controlled.

However, the method of operating the quantum device is not limited thereto. Although not illustrated, in another example, another method of operating a quantum device (e.g., the quantum device 200), the quantum device may have a discrete resonant frequency by directly applying a current to its ferromagnetic link (e.g., the ferromagnetic link 230). For example, by applying a first current or a second current to the ferromagnetic link, the quantum device may be controlled to have the first resonant frequency F1 or the second resonant frequency F2.

For example, by controlling the direction of a current applied to the ferromagnetic link, the magnetization configuration of a magnetization control region (e.g., the magnetization control region 231) and the resonant frequency of the quantum device may be discretely adjusted.

As the first current is applied to the ferromagnetic link, the magnetization configuration of the magnetization control region may be arranged in the first arrangement. As skyrmions are generated in the magnetization control region, the quantum device may have the first resonant frequency F1. Then, as the second current is applied to the ferromagnetic link, the magnetization configuration of the magnetization control region may be changed to the second arrangement. In this state, the second current may be a current with the same magnitude as and opposite direction from the first current. As the skyrmions of the magnetization control region are destroyed, the quantum device may have the second resonant frequency F2.

The magnetization configuration of the magnetization control region may be controlled to have the first arrangement or the second arrangement by the currents applied to the ferromagnetic link at different times, and thus, in response to each current, the resonant frequency of the quantum device may be also tuned to the first resonant frequency F1 or the second resonant frequency F2.

However, examples the method of operating the quantum device using the direct application of a current are not limited thereto. In another example, by controlling the magnitude of a current applied to a ferromagnetic link (e.g., the ferromagnetic link 230), the magnetization configuration of its magnetization control region (e.g., the magnetization control region 231) and the resonant frequency of its quantum device (e.g., the quantum device 200) may be discretely adjusted.

The magnitude or direction of a current to discretely control the quantum device may be determined based on the properties of the ferromagnetic link. By applying a current with fixed magnitude and direction to the ferromagnetic link with a time difference, the generation or destruction of skyrmions in the magnetization control region may be repeatedly reproduced, and as a result, the resonant frequency of the quantum device may also be repeatedly reproduced as the first resonant frequency or the second resonant frequency.

In an example, a quantum device (e.g., quantum device 200) may be a cubit or a cubit coupler. The descriptions presented above with reference to FIGS. 1 to 6 may be used for various operations of quantum devices, such as setting the resonant frequency of a cubit/cubit coupler to a preset resonant frequency, setting the energy level of a cubit/a cubit coupler, changing the resonant frequency of a cubit/a cubit coupler, coupling cubits, or decoupling cubits.

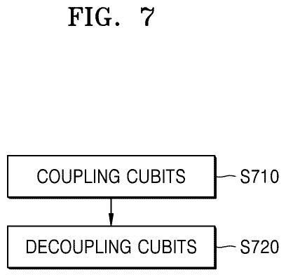

FIG. 7 illustrates an example method of operating a cubit coupler according to one or more embodiments.

In an example, a cubit coupler may include a ferromagnetic link(e.g., the ferromagnetic link 230), and a first superconducting layer (e.g., the first superconducting layer 110) and a second superconducting layer (e.g., the second superconducting layer 120) that are coupled to each other by the ferromagnetic link. The ferromagnetic link may include a magnetization control region (e.g., the magnetization control region 231), and a magnetization configuration of the magnetization control region may be changed by an external signal. The magnetization configuration of the magnetization control region may be arranged to correspond to a frequency for coupling or decoupling cubits connected to the cubit coupler.

In an example, in operation S710, the cubit coupler may couple cubits.

By applying a first external signal to the cubit coupler, the magnetization configuration of the ferromagnetic link may be arranged in a first arrangement. As the magnetization configuration of the ferromagnetic link is arranged in the first arrangement, skyrmions may be generated in the magnetization control region, and thus, the cubit coupler may have a first resonant frequency.

For example, the first external signal may be an external magnetic field or an external electric field applied to the cubit coupler. However, the examples are not limited thereto, and in another example, the first external signal may be a current or a laser pulse (e.g., the first laser pulse 611 and the second laser pulse 612) applied to the ferromagnetic link.

Furthermore, even when the first external signal is removed, the magnetization configuration of the ferromagnetic link may be maintained in the first arrangement. In particular, as the skyrmions have topological stability, the skyrmions may be protected from external noise. Accordingly, the resonant frequency of the cubit coupler may be maintained in the first resonant frequency. While the resonant frequency of the cubit coupler is maintained in the first resonant frequency, a state in which the cubits connected to the cubit coupler are coupled to each other may be maintained.

In an example, in operation S720, the cubit coupler may decouple the cubits.

By applying a second external signal to the cubit coupler, the magnetization configuration of the ferromagnetic link may be arranged in a second arrangement. As the magnetization configuration of the ferromagnetic link is arranged in the second arrangement, the skyrmions in the magnetization control region may be destroyed, and thus, the cubit coupler may have a second resonant frequency.

For example, the second external signal may be an external magnetic field, an external electric field, or a current having a different magnitude or direction from the first external signal. However, the disclosure is not limited thereto, and the second external signal may be a laser pulse having a different strength or duration from the first external signal.

Furthermore, even when the second external signal is removed, the magnetization configuration of the ferromagnetic link may be maintained in the second arrangement. Unless energy over the energy for generating skyrmions is applied to the ferromagnetic link, the magnetization configuration of the ferromagnetic link may be maintained in the second arrangement. Accordingly, the resonant frequency of the cubit coupler may be maintained as the second resonant frequency. While the resonant frequency of the cubit coupler is maintained as the second resonant frequency, a state in which the cubits connected to the cubit coupler are decoupled may be maintained.

However, a correlation between the states of the cubits connected to the cubit coupler and external signals applied to the cubit coupler is not limited to the descriptions presented above. In another example, when the first external signal is applied to the cubit coupler, a state in which the cubits connected to the cubit coupler are decoupled may be maintained, and when the second external signal is applied to the cubit coupler, a state in which the cubits connected to the cubit coupler are coupled may be maintained.

In detail, while the resonant frequency of the cubit coupler is maintained as the first resonant frequency as the first external signal is applied to the cubit coupler, a state in which the cubits connected to the cubit coupler are decoupled may be maintained, and while the resonant frequency of the cubit coupler is maintained as the second resonant frequency as the second external signal is applied to the cubit coupler, a state in which the cubits connected to the cubit coupler are coupled may be maintained.

It should be understood that the quantum device with a tunable resonant frequency, and the methods of operating thereof, according to the examples, described herein should be considered in a descriptive sense only and not for purposes of limitation. Descriptions of features or aspects within each embodiment should typically be considered as available for other similar features or aspects in other embodiments. For example, each constituent element described to be a single type may be embodied in a distributive manner. Likewise, the constituent elements described to be distributed may be embodied in a combined form.

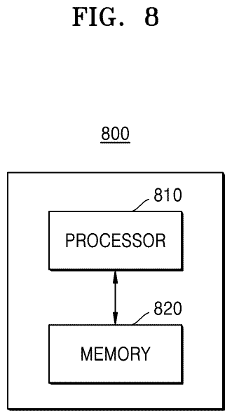

FIG. 8 illustrates an example electronic device with a superconducting quantum circuit system according to one or more embodiments.

Referring to FIG. 8, in a non-limiting example, an electronic device 800 may control a superconducting quantum circuit system, and the electronic device 800 may include a processor 810 and a memory 820. In an example, the processor 810 may be or control a control circuit (e.g., control circuit 320) for a quantum device (e.g., quantum device 200) and/or a current pulse supply device of a quantum device or superconducting quantum circuit system that provides a control signal such as a current pulse (e.g., the first current pulse 410 and second current pulse 420 of FIGS. 4A and 4B), a laser (e.g., the first laser pulse 611 and second laser pulse 612 of FIG. 6) from laser device 540, or other control signals.

The processor 810 may be one or more processors or processing elements. The processor 810 may be configured to execute programs or applications to configure the processor 810 to control the electronic apparatus 800 to perform one or more or all operations and/or methods involving the control of a superconducting quantum circuit system including the control circuit and/or current pulse supply device, and may include any one or a combination of two or more of, for example, a central processing unit (CPU), a graphic processing unit (GPU), a neural processing unit (NPU) and tensor processing units (TPUs), but is not limited to the above-described examples.

The memory 820 may include computer-readable instructions. The processor 810 may be configured to execute computer-readable instructions, such as those stored in the memory 820, and through execution of the computer-readable instructions, the processor 810 is configured to perform one or more, or any combination, of the operations and/or methods described herein. The memory 820 may be a volatile or nonvolatile memory.

The superconducting quantum circuit systems, electronic devices, memories, processors, current pulse supply devices, Josephson junctions, quantum device 100, first superconducting layer 110, second superconducting layer 120, ferromagnetic link 130, quantum device 200, first superconducting layer 210, second superconducting layer 220, ferromagnetic link 230, magnetization control region 231, quantum circuit 500, quantum circuit 510, quantum circuit 520, control circuit 530, laser device 540, electronic device 800, processor 810, and memory 820 described herein and disclosed herein described with respect to FIGS. 1-8 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-8 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A quantum device with a tunable resonant frequency, the quantum device comprising:
a ferromagnetic link comprising a ferromagnetic material; and
a first superconducting layer and a second superconducting layer coupled to each other by the ferromagnetic link,
wherein the ferromagnetic link is configured in a magnetization configuration arranged in a first arrangement corresponding to a first resonant frequency of the quantum device or in a second arrangement corresponding to a second resonant frequency of the quantum device.

2. The quantum device of claim 1, wherein the magnetization configuration is configured to generate skyrmions in the first arrangement and to destroy the skyrmions in the second arrangement.

3. The quantum device of claim 1, wherein the tunable resonant frequency is discretely tuned based on an arrangement of the magnetization configuration.

4. The quantum device of claim 1, wherein the magnetization configuration is changed by an applied external signal to be arranged in the first arrangement or the second arrangement.

5. The quantum device of claim 1, wherein the tunable resonant frequency of the quantum device is determined as an arrangement of the magnetization configuration,
and wherein the magnetization configuration is changed by an applied external signal.

6. The quantum device of claim 1, wherein an application of an external signal causes a formation of skyrmions to form to implement one of the first resonant frequency and the second resonant frequency.

7. The quantum device of claim 1, wherein, each of the first resonant frequency and the second resonant frequency are reproducible in response to respective external signals being applied to the ferromagnetic link.

8. The quantum device of claim 1, wherein the magnetization configuration is arranged in the first arrangement in response to a first external signal, and
wherein the magnetization configuration is changed from the first arrangement to the second arrangement in response to a second external signal.

9. The quantum device of claim 8, further comprising:
a wire arranged adjacent to the ferromagnetic link;
processors configured to execute instructions; and
a memory storing the instructions, wherein execution of the instructions configures the processors to:
control an electric current flowing through the wire to create external magnetic fields to generate the first external signal and the second external signal, and
wherein the first external signal and the second external signal are selectively applied to the ferromagnetic link by the wire.

10. The quantum device of claim 9, wherein an arrangement of the magnetization configuration is determined based on a direction or a strength of the electric current applied to the ferromagnetic link.

11. The quantum device of claim 1, wherein, when a first current in a first direction is applied to the ferromagnetic link, the magnetization configuration is arranged in the first arrangement, and
wherein, when a second current in a second direction opposite to the first direction is applied to the ferromagnetic link, the magnetization configuration is changed from the first arrangement to the second arrangement.

12. The quantum device of claim 1, further comprising:
a laser configured to apply laser pulses to the ferromagnetic link;
processors configured to execute instructions; and
a memory storing the instructions, wherein execution of the instructions configures the processors to:
control a strength of a laser pulse of the laser pulses being selectively applied to the ferromagnetic link to change an arrangement of the magnetization configuration.

13. The quantum device of claim 12, wherein a time to rearrange the magnetization configuration is determined based on a duration of the laser pulse applied to the ferromagnetic link.

14. The quantum device of claim 1, wherein the quantum device comprises a cubit of a quantum circuit.

15. The quantum device of claim 1, wherein the quantum device comprises a cubit coupler of a quantum circuit.

16. An method of controlling a cubit coupler, the method comprising:
coupling cubits by applying a first external signal to the cubit coupler to allow a magnetization configuration of a ferromagnetic link, the ferromagnetic link being configured to couple a first superconducting layer and a second superconducting layer of the cubit coupler, to be arranged in a first arrangement to configure the cubit coupler to have a first resonant frequency; and
decoupling the cubits by applying a second external signal to the cubit coupler to allow the magnetization configuration of the ferromagnetic link to be arranged in a second arrangement to configure the cubit coupler to have a second resonant frequency.

17. The method of claim 16, wherein the magnetization configuration is configured to generate skyrmions in the first arrangement and to destroy the skyrmions in the second arrangement.

18. The method of claim 16, wherein the coupling of the cubits comprises:
applying the first external signal to align the magnetization configuration to be arranged in the first arrangement; and
removing the first external signal to allow a resonant frequency of the cubit coupler to be maintained as the first resonant frequency.

19. The method of claim 16, wherein the decoupling of the cubits comprises:
applying the second external signal to align the magnetization configuration to be arranged in the second arrangement; and
removing the second external signal to allow a resonant frequency of the cubit coupler to be maintained as the second resonant frequency.

20. The method of claim 16, further comprising:
applying the first external signal and the second external signal to the ferromagnetic link,
wherein the first external signal and the second external signal comprise one of:
a first external magnetic field and a second external magnetic field, the first external magnetic field and the second external magnetic field having different strengths or directions;
a first electric current and a second electric current, the first electric current and the second electric current having different directions or strengths; and
a first laser pulse and a second laser pulse, the first laser pulse and the second laser pulse having different strengths.
